(19) United States
(12) Patent Application Publication
(10) Pub. No.: US 2024/0364318 A1
(43) Pub. Date: Oct. 31, 2024

(54) Electronic Device with Digital Frequency Discriminator for Wireless Communication

(71) Applicant: Apple Inc., Cupertino, CA (US)

(72) Inventors: Zdravko Boos, Munich (DE); Andreas Menkhoff, Oberhaching (DE); Bertram R Gunzelmann, Koenigsbrunn (DE); Nedim Muharemovic, Nuremberg (DE)

(21) Appl. No.: 18/308,221

(22) Filed: Apr. 27, 2023

(51) Int. Cl. H03K 5/01; H03D 7/00

(52) U.S. Cl. CPC H03K 5/01; H03D 7/00; G04F 10/005; H03K 2005/00078; H03K 2005/00286

(57) ABSTRACT

An electronic device may include wireless circuitry that conveys wireless signals and that is clocked using clocking circuitry. The clocking circuitry may include a signal source that generates a clock signal and a loop path coupled between the input and the output of the signal source. A digital frequency discriminator (DFD) may be disposed on the loop path. The DFD may include a digital delay and digital phase shifter coupled between an input converter and a digital mixer. The DFD may receive the clock signal and may generate a control signal indicative of phase noise of the clock signal. The DFD may feed the control signal back into the input of the signal source to mitigate the phase noise. The DFD may minimize phase noise of the signal source while minimizing space and power consumption on the device relative to analog frequency discriminators.

### FIELD

This disclosure relates generally to electronic devices and, more particularly, to electronic devices with wireless circuitry.

### BACKGROUND

Electronic devices can be provided with wireless capabilities. An electronic device with wireless capabilities has wireless circuitry that includes one or more antennas. The wireless circuitry is used to perform communications using radio-frequency signals conveyed by the antennas.

As software applications on electronic devices become more data-intensive over time, demand has grown for electronic devices that support wireless communications at higher data rates. However, the maximum data rate supported by electronic devices is limited by the frequency of the radio-frequency signals. As communication frequencies increase, it can become difficult to provide low phase noise clocking for the wireless circuitry.

### SUMMARY

An electronic device may include wireless circuitry that conveys wireless signals. The wireless circuitry may be clocked using clocking circuitry. The clocking circuitry may include a signal source and a loop path coupled between the input and the output of the signal source. The signal source may generate a clock signal used to convey wireless signals. The clock signal may be a radio-frequency signal or an optical signal. An antenna may transmit and/or receive wireless signals based on the clock signal.

A digital frequency discriminator (DFD) may be disposed on the loop path. The DFD may receive the clock signal and may generate a control signal indicative of phase noise of the clock signal. The DFD may feed the control signal back into the input of the signal source. The signal source may adjust the clock signal based on the control signal to mitigate the phase noise measured by the DFD.

The DFD may include an input converter that converts the clock signal into a digital signal. The input converter may be a time-to-digital converter (TDC) or an analog-to-digital converter (ADC). The input converter may be coupled to a digital mixer over a first digital path and a second digital path parallel to the first digital path. Digital delay circuitry may be disposed on the first digital path. A digital phase shifter may be disposed on the second digital path. The digital delay circuitry may generate a delayed signal by passing the digital signal through one or more delay stages coupled in series and/or parallel. The digital phase shifter may generate a phase shifted signal by applying a 90-degree phase shift to the digital signal. The mixer may generate the control signal by mixing the delayed signal with the phase shifted signal.

The DFD may pass the control signal to the signal source in the digital domain or the DFD may include an output converter that converts the control signal out of the digital domain prior to passing the control signal to the signal source. The output converter may be a digital-to-time converter (DTC) or a digital-to-analog converter (DAC). If desired, the DFD may include a filter to filter the control signal. The DFD may minimize phase noise of the signal source while minimizing space and power consumption on the device relative to analog frequency discriminators.

An aspect of the disclosure provides an electronic device. The electronic device can include a signal source configured to generate a clock signal. The electronic device can include a loop path that couples an output of the signal source to an input of the signal source. The electronic device can include a frequency discriminator disposed on the loop path, the frequency discriminator including a converter having an input communicably coupled to the output of the signal source, a digital mixer having an output communicably coupled to the input of the signal source, a digital delay coupled between the converter and the digital mixer, and a digital phase shifter coupled between the converter and the digital mixer in parallel with the digital delay.

An aspect of the disclosure provides a frequency discriminator. The frequency discriminator can include an input converter. The frequency discriminator can include a digital mixer having a first input coupled to an output of the input converter over a first path and having a second input coupled to the output of the input converter over a second path parallel to the first path. The frequency discriminator can include a digital delay circuit disposed on the first path. The frequency discriminator can include a digital phase shifter disposed on the second path. The frequency discriminator can include an output converter coupled to an output of the digital mixer.

An aspect of the disclosure provides an electronic device. The electronic device can include an antenna radiating element. The electronic device can include a photodiode coupled to the antenna radiating element. The electronic device can include a first light source configured to generate a first optical local oscillator (LO) signal that illuminates the photodiode. The electronic device can include a second light source configured to generate a second optical LO signal that illuminates the photodiode. The electronic device can include a frequency discriminator coupled between an output of the first light source and an input of the first light source, the frequency discriminator including a converter configured to convert an input signal into a digital signal, and digital circuitry configured to generate a control signal based on the digital signal, the control signal being indicative of a phase noise of the input signal.

### BRIEF DESCRIPTION OF THE DRAWINGS

FIG. 1 is a block diagram of an illustrative electronic device having wireless circuitry that is clocked using clocking circuitry in accordance with some embodiments.

FIG. 2 is a top view of an illustrative antenna that transmits wireless signals at frequencies greater than about 100 GHz based on optical local oscillator (LO) signals in accordance with some embodiments.

FIG. 3 is a top view showing how an illustrative antenna of the type shown in FIG. 2 may convert received wireless signals at frequencies greater than about 100 GHz into intermediate frequency signals based on optical LO signals in accordance with some embodiments.

FIG. 4 is a top view showing how multiple antennas of the type shown in FIGS. 2 and 3 may be stacked to cover multiple polarizations in accordance with some embodiments.

FIG. 5 is a top view showing how stacked antennas of the type shown in FIG. 4 may be integrated into a phased antenna array for conveying wireless signals at frequencies greater than about 100 GHz within a corresponding signal beam.

FIG. 6 is a circuit diagram of illustrative wireless circuitry having an antenna that transmits wireless signals at frequencies greater than about 100 GHz and that receives wireless signals at frequencies greater than about 100 GHz for conversion to intermediate frequencies and then to the optical domain in accordance with some embodiments.

FIG. 7 is a circuit diagram of an illustrative phased antenna array that conveys wireless signals at frequencies greater than about 100 GHz within a corresponding signal beam in accordance with some embodiments.

FIG. 8 is a circuit diagram of illustrative clocking circuitry having a digital frequency discriminator in accordance with some embodiments.

FIG. 9 is a circuit diagram of an illustrative digital frequency discriminator in accordance with some embodiments.

FIG. 10 is a circuit diagram of illustrative delay circuitry in a digital frequency discriminator having multiple parallel-coupled delay stages in accordance with some embodiments.

FIG. 11 is a circuit diagram of illustrative delay circuitry in a digital frequency discriminator having multiple series-coupled delay stages in accordance with some embodiments.

FIG. 12 is a circuit diagram of illustrative clocking circuitry having first and second light sources that are controlled using a digital frequency discriminator in accordance with some embodiments.

FIG. 13 is a plot of phase noise as a function of frequency showing how illustrative delay circuitry in a digital frequency discriminator may smooth spurious phase noise in accordance with some embodiments.

### DETAILED DESCRIPTION

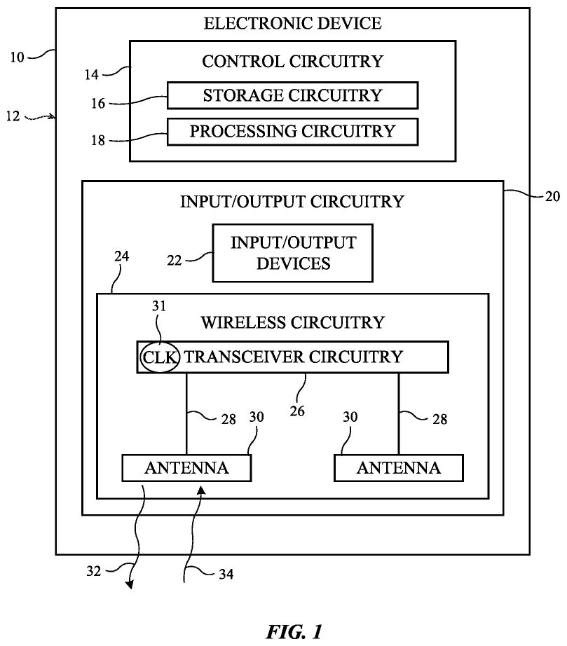

Electronic device 10 of FIG. 1 (sometimes referred to herein as electro-optical device 10) may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, parts or all of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), temperature sensors, etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas 30. Wireless circuitry 24 may also include transceiver circuitry 26. Transceiver circuitry 26 may include transmitter circuitry, receiver circuitry, modulator circuitry, demodulator circuitry (e.g., one or more modems), radio-frequency circuitry, one or more radios, intermediate frequency circuitry, optical transmitter circuitry, optical receiver circuitry, optical light sources, other optical components, baseband circuitry (e.g., one or more baseband processors), amplifier circuitry, clocking circuitry such as one or more local oscillators and/or phase-locked loops, memory, one or more registers, filter circuitry, switching circuitry, analog-to-digital converter (ADC) circuitry, digital-to-analog converter (DAC) circuitry, radio-frequency transmission lines, optical fibers, and/or any other circuitry for transmitting and/or receiving wireless signals using antennas 30. The components of transceiver circuitry 26 may be implemented on one integrated circuit, chip, system-on-chip (SOC), die, printed circuit board, substrate, or package, or the components of transceiver circuitry 26 may be distributed across two or more integrated circuits, chips, SOCs, printed circuit boards, substrates, and/or packages.

The example of FIG. 1 is illustrative and non-limiting. While control circuitry 14 is shown separately from wireless circuitry 24 in the example of FIG. 1 for the sake of clarity, wireless circuitry 24 may include processing circuitry (e.g., one or more processors) that forms a part of processing circuitry 18 and/or storage circuitry that forms a part of storage circuitry 16 of control circuitry 14 (e.g., portions of control circuitry 14 may be implemented on wireless circuitry 24). As an example, control circuitry 14 may include baseband circuitry (e.g., one or more baseband processors), digital control circuitry, analog control circuitry, and/or other control circuitry that forms part of wireless circuitry 24. The baseband circuitry may, for example, access a communication protocol stack on control circuitry 14 (e.g., storage circuitry 20) to: perform user plane functions at a PHY layer, MAC layer, RLC layer, PDCP layer, SDAP layer, and/or PDU layer, and/or to perform control plane functions at the PHY layer, MAC layer, RLC layer, PDCP layer, RRC, layer, and/or non-access stratum layer.

Transceiver circuitry 26 may be coupled to each antenna 30 in wireless circuitry 24 over a respective signal path 28. Each signal path 28 may include one or more radio-frequency transmission lines, waveguides, optical fibers, and/or any other desired lines/paths for conveying wireless signals between transceiver circuitry 26 and antenna 30. Antennas 30 may be formed using any desired antenna structures for conveying wireless signals. For example, antennas 30 may include antennas with resonating elements that are formed from dipole antenna structures, planar dipole antenna structures (e.g., bowtie antenna structures), slot antenna structures, loop antenna structures, patch antenna structures, inverted-F antenna structures, planar inverted-F antenna structures, helical antenna structures, monopole antennas, dipoles, hybrids of these designs, etc. Filter circuitry, switching circuitry, impedance matching circuitry, and/or other antenna tuning components may be adjusted to adjust the frequency response and wireless performance of antennas 30 over time.

If desired, two or more of antennas 30 may be integrated into a phased antenna array (sometimes referred to herein as a phased array antenna) in which each of the antennas conveys wireless signals with a respective phase and magnitude that is adjusted over time so the wireless signals constructively and destructively interfere to produce (form) a signal beam in a given pointing direction. The term “convey wireless signals” as used herein means the transmission and/or reception of the wireless signals (e.g., for performing unidirectional and/or bidirectional wireless communications with external wireless communications equipment). Antennas 30 may transmit the wireless signals by radiating the signals into free space (or to free space through intervening device structures such as a dielectric cover layer). Antennas 30 may additionally or alternatively receive the wireless signals from free space (e.g., through intervening devices structures such as a dielectric cover layer). The transmission and reception of wireless signals by antennas 30 each involve the excitation or resonance of antenna currents on an antenna resonating (radiating) element in the antenna by the wireless signals within the frequency band(s) of operation of the antenna.

Transceiver circuitry 26 may use antenna(s) 30 to transmit and/or receive wireless signals that convey wireless communications data between device 10 and external wireless communications equipment (e.g., one or more other devices such as device 10, a wireless access point or base station, etc.). The wireless communications data may be conveyed bidirectionally or unidirectionally. The wireless communications data may, for example, include data that has been encoded into corresponding data packets such as wireless data associated with a telephone call, streaming media content, internet browsing, wireless data associated with software applications running on device 10, email messages, etc.

Additionally or alternatively, wireless circuitry 24 may use antenna(s) 30 to perform wireless sensing operations. The sensing operations may allow device 10 to detect (e.g., sense or identify) the presence, location, orientation, and/or velocity (motion) of objects external to device 10. Control circuitry 14 may use the detected presence, location, orientation, and/or velocity of the external objects to perform any desired device operations. As examples, control circuitry 14 may use the detected presence, location, orientation, and/or velocity of the external objects to identify a corresponding user input for one or more software applications running on device 10 such as a gesture input performed by the user's hand(s) or other body parts or performed by an external stylus, gaming controller, head-mounted device, or other peripheral devices or accessories, to determine when one or more antennas 30 needs to be disabled or provided with a reduced maximum transmit power level (e.g., for satisfying regulatory limits on radio-frequency exposure), to determine how to steer (form) a radio-frequency signal beam produced by antennas 30 for wireless circuitry 24 (e.g., in scenarios where antennas 30 include a phased array of antennas 30), to map or model the environment around device 10 (e.g., to produce a software model of the room where device 10 is located for use by an augmented reality application, gaming application, map application, home design application, engineering application, etc.), to detect the presence of obstacles in the vicinity of (e.g., around) device 10 or in the direction of motion of the user of device 10, etc.

Wireless circuitry 24 may transmit and/or receive wireless signals within corresponding frequency bands of the electromagnetic spectrum (sometimes referred to herein as communications bands or simply as “bands”). The frequency bands handled by communications circuitry 26 may include wireless local area network (WLAN) frequency bands (e.g., Wi-Fi® (IEEE 802.11) or other WLAN communications bands) such as a 2.4 GHz WLAN band (e.g., from 2400 to 2480 MHZ), a 5 GHz WLAN band (e.g., from 5180 to 5825 MHZ), a Wi-Fi® 6E band (e.g., from 5925-7125 MHZ), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHZ to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, near-field communications frequency bands (e.g., at 13.56 MHZ), satellite navigation frequency bands (e.g., a GPS band from 1565 to 1610 MHZ, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

Over time, software applications on electronic devices such as device 10 have become more and more data intensive. Wireless circuitry on the electronic devices therefore needs to support data transfer at higher and higher data rates. In general, the data rates supported by the wireless circuitry are proportional to the frequency of the wireless signals conveyed by the wireless circuitry (e.g., higher frequencies can support higher data rates than lower frequencies). Wireless circuitry 24 may convey centimeter and millimeter wave signals to support relatively high data rates (e.g., because centimeter and millimeter wave signals are at relatively high frequencies between around 10 GHz and 100 GHz). However, the data rates supported by centimeter and millimeter wave signals may still be insufficient to meet all the data transfer needs of device 10. To support even higher data rates such as data rates up to 5-10 Gbps or higher, wireless circuitry 24 may convey wireless signals at frequencies greater than 100 GHz.

As shown in FIG. 1, wireless circuitry 24 may transmit wireless signals 32 and may receive wireless signals 34 at frequencies greater than around 100 GHz. Wireless signals 32 and 34 may sometimes be referred to herein as tremendously high frequency (THF) signals 32 and 34, sub-THz signals 32 and 34, THz signals 32 and 34, or sub-millimeter wave signals 32 and 34. THF signals 32 and 34 may be at sub-THz or THz frequencies such as frequencies between 100 GHz and 1 THz, between 100 GHz and 10 THz, between 100 GHz and 2 THz, between 200 GHz and 1 THz, between 300 GHz and 1 THz, between 300 GHz and 2 THz, between 300 GHz and 10 THz, between 100 GHz and 800 GHz, between 200 GHz and 1.5 THz, etc. (e.g., within a sub-THz, THz, THF, or sub-millimeter frequency band such as a 6G frequency band).

The high data rates supported by these frequencies may be leveraged by device 10 to perform cellular telephone voice and/or data communications (e.g., while supporting spatial multiplexing to provide further data bandwidth), to perform spatial ranging operations such as radar operations to detect the presence, location, and/or velocity of objects external to device 10, to perform automotive sensing (e.g., with enhanced security), to perform health/body monitoring on a user of device 10 or another person, to perform gas or chemical detection, to form a high data rate wireless connection between device 10 and another device or peripheral device (e.g., to form a high data rate connection between a display driver on device 10 and a display that displays ultra-high resolution video), to form a remote radio head (e.g., a flexible high data rate connection), to form a THF chip-to-chip connection within device 10 that supports high data rates (e.g., where one antenna 30 on a first chip in device 10 transmits THF signals 32 to another antenna 30 on a second chip in device 10), and/or to perform any other desired high data rate operations.

Wireless circuitry 30 may include one or more antennas 30 for conveying THF signals and/or may include one or more antennas 30 for conveying non-THF signals (e.g., at frequencies less than around 100 GHz). Transceiver circuitry 26 may include clocking (CLK) circuitry such as clocking circuitry 31 (sometimes referred to herein as clock circuitry 31). Clocking circuitry 31 may generate one or more clock signals (e.g., local oscillator signals) that are used by transceiver circuitry 26 to transmit and/or receive signals (e.g., THF signals and/or non-THF signals).

The clock signals may, for example, be provided as an input to one or more mixers in transceiver circuitry 26 for converting signals between different frequencies (e.g., between baseband frequencies, intermediate frequencies, radio frequencies, optical frequencies, etc.). The mixers may include one or more radio mixers (e.g., for converting between radio, intermediate, and/or baseband frequencies) and/or one or more electro-optical (EO) mixers (e.g., for converting between radio frequencies and optical frequencies or between optical frequencies). The EO mixers may sometimes be referred to herein as photo mixers and may include photodiodes (e.g., uni-travelling-carrier photodiodes (UTC PD)), electrooptical modulators (e.g., Mach-Zehnder modulators), and/or other mixers for converting signals from radio frequencies to optical frequencies and/or from optical frequencies to radio frequencies. Transceiver circuitry 26 may use radio mixers to convey non-THF signals whereas one or both of radio mixers and EO mixers may be used to convey THF signals, for example.

If desired, clocking circuitry 31 may include one or more phase locked loops (PLLs), frequency locked loops (FLLs), self-injection locking (SIL) loops, or other circuitry that serves to process the clock signals generated by the clocking circuitry (e.g., to phase-lock the clock signals, to frequency-lock the clock signals, to self-injection lock the clock signals, etc.). While shown in transceiver circuitry 26 in FIG. 1, clocking circuitry 31 may be located elsewhere in wireless circuitry 24 or device 10. In general, clocking circuitry 31 may be used to clock any desired processing operations performed by control circuitry 14 on device 10 (e.g., clocking circuitry 31 need not be used to clock the transmission or reception of wireless signals).

Implementations in which wireless circuitry 24 conveys THF signals using electro-optical circuitry are described herein as an example. However, in general, wireless circuitry 24 may convey non-THF signals in addition to or instead of THF signals. In implementations where wireless circuitry 24 conveys THF signals, different antennas 30 may be used to transmit THF signals 32 than are used to receive THF signals 34. However, space is at a premium within electronic devices such as device 10. Handling transmission of THF signals 32 and reception of THF signals 34 using different antennas 30 can consume an excessive amount of space and other resources within device 10 because two antennas 30 and signal paths 28 would be required to handle both transmission and reception. To minimize space and resource consumption within device 10, the same antenna 30 and signal path 28 may be used to both transmit THF signals 32 and to receive THF signals 34. If desired, multiple antennas 30 in wireless circuitry 24 may transmit THF signals 32 and may receive THF signals 34. The antennas may be integrated into a phased antenna array that transmits THF signals 32 and that receives THF signals 34 within a corresponding signal beam oriented in a selected beam pointing direction.

It can be challenging to incorporate components into wireless circuitry 24 that support wireless communications at these high frequencies. If desired, transceiver circuitry 26 and signal paths 28 may include optical components that convey optical signals to support the transmission of THF signals 32 and the reception of THF signals 34 in a space and resource-efficient manner. The optical signals may be used in transmitting THF signals 32 at THF frequencies and in receiving THF signals 34 at THF frequencies.

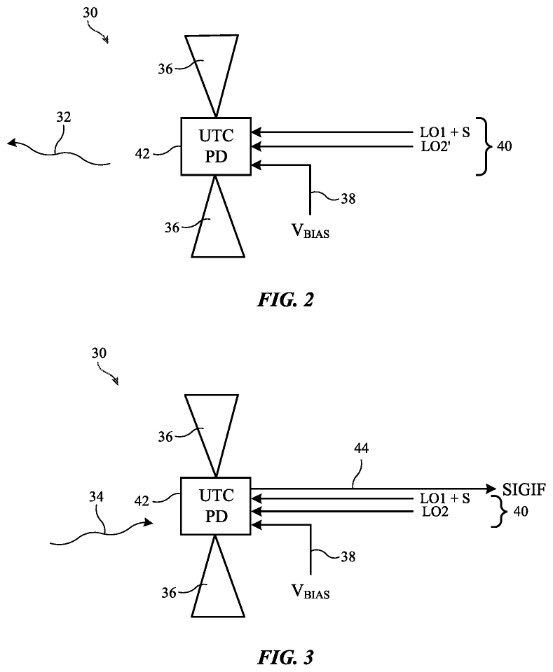

FIG. 2 is a diagram of an illustrative antenna 30 that may be used to both transmit THF signals 32 and to receive THF signals 34 using optical signals. Antenna 30 may include one or more antenna radiating (resonating) elements such as radiating (resonating) element arms 36. In the example of FIG. 2, antenna 30 is a planar dipole antenna (sometimes referred to as a “bowtie” antenna) having two opposing radiating element arms 36 (e.g., bowtie arms or dipole arms). This is illustrative and non-limiting. In general, antenna 30 may be any type of antenna having any desired antenna radiating element architecture.

As shown in FIG. 2, antenna 30 includes a photodiode (PD) 42 coupled between radiating element arms 36. Electronic devices that include antennas 30 with photodiodes 42 such as device 10 may sometimes also be referred to as electro-optical devices (e.g., electro-optical device 10). Photodiode 42 may be a programmable photodiode. An example in which photodiode 42 is a programmable uni-travelling-carrier photodiode (UTC PD) is described herein as an example. Photodiode 42 may therefore sometimes be referred to herein as UTC PD 42 or programmable UTC PD 42. This is illustrative and non-limiting. In general, photodiode 42 may include any desired type of adjustable/programmable photodiode or component that converts electromagnetic energy (e.g., light or light energy) at optical frequencies (e.g., infrared, visible, and/or ultraviolet frequencies) to current at THF frequencies on radiating element arms 36 and/or vice versa. Each radiating element arm 36 may, for example, have a first edge at UTC PD 42 and a second edge opposite the first edge that is wider than the first edge (e.g., in implementations where antenna 30 is a bowtie antenna). Other radiating elements may be used if desired.

UTC PD 42 may have a bias terminal 38 that receives one or more control signals V_{BIAS}. Control signals V_{BIAS} may include bias voltages provided at one or more voltage levels and/or other control signals for controlling the operation of UTC PD 42 such as impedance adjustment control signals for adjusting the output impedance of UTC PD 42. Control circuitry 14 (FIG. 1) may provide (e.g., apply, supply, assert, etc.) control signals V_{BIAS} at different settings (e.g., values, magnitudes, etc.) to dynamically control (e.g., program or adjust) the operation of UTC PD 42 over time. For example, control signals V_{BIAS} may be used to control whether antenna 30 transmits THF signals 32 or receives THF signals 34. When control signals V_{BIAS} include a bias voltage asserted at a first level or magnitude, antenna 30 may be configured to transmit THF signals 32. When control signals V_{BIAS} include a bias voltage asserted at a second level or magnitude, antenna 30 may be configured to receive THF signals 34. In the example of FIG. 2. control signals V_{BIAS} include the bias voltage asserted at the first level to configure antenna 30 to transmit THF signals 32. If desired, control signals V_{BIAS} may also be adjusted to control the waveform of the THF signals (e.g., as a squaring function that preserves the modulation of incident optical signals, a linear function, etc.), to perform gain control on the signals conveyed by antenna 30, and/or to adjust the output impedance of UTC PD 42.

As shown in FIG. 2. UTC PD 42 may be optically coupled to optical path 40. Optical path 40 may include one or more optical fibers or waveguides. UTC PD 42 may receive optical signals from transceiver circuitry 26 (FIG. 1) over optical path 40. The optical signals may include a first optical local oscillator (LO) signal LO1 and a second optical local oscillator signal LO2. Optical local oscillator signals LO1 and LO2 may be generated by light sources in transceiver circuitry 26 (FIG. 1). Optical local oscillator signals LO1 and LO2 may be at optical wavelengths (e.g., between 400 nm and 700 nm), ultra-violet wavelengths (e.g., near-ultra-violet or extreme ultraviolet wavelengths), and/or infrared wavelengths (e.g., near-infrared wavelengths, mid-infrared wavelengths, or far-infrared wavelengths). Optical local oscillator signal LO2 may be offset in wavelength from optical local oscillator signal LO1 by a wavelength offset X. Wavelength offset X may be equal to the wavelength of the THF signals conveyed by antenna 30 (e.g., between 100 GHz and 1 THz (1000 GHz), between 100 GHz and 2 THz. between 300 GHz and 800 GHz, between 300 GHz and 1 THz, between 300 and 400 GHz, etc.).

During signal transmission, wireless data (e.g., wireless data packets, symbols, frames, etc.) may be modulated onto optical local oscillator signal LO2 to produce modulated optical local oscillator signal LO2′. If desired, optical local oscillator signal LO1 may be provided with an optical phase shift S. Optical path 40 may illuminate UTC PD 42 with optical local oscillator signal LO1 (plus the optical phase shift S when applied) and modulated optical local oscillator signal LO2′. If desired, lenses or other optical components may be interposed between optical path 40 and UTC PD 42 to help focus the optical local oscillator signals onto UTC PD 42.

UTC PD 42 may convert optical local oscillator signal LO1 and modulated local oscillator signal LO2′ (e.g., beats between the two optical local oscillator signals) into antenna currents that run along the perimeter of radiating element arms 36. The frequency of the antenna currents is equal to the frequency difference between local oscillator signal LO1 and modulated local oscillator signal LO2′. The antenna currents may radiate (transmit) THF signals 32 into free space. Control signal V_{BIAS} may control UTC PD 42 to convert the optical local oscillator signals into antenna currents on radiating element arms 36 while preserving the modulation and thus the wireless data on modulated local oscillator signal LO2′ (e.g., by applying a squaring function to the signals). THF signals 32 will thereby carry the modulated wireless data for reception and demodulation by external wireless communications equipment.

FIG. 3 is a diagram showing how antenna 30 may receive THF signals 34 (e.g., after changing the setting of control signals V_{BIAS} into a reception state from the transmission state of FIG. 2). As shown in FIG. 3. THF signals 34 may be incident upon antenna radiating element arms 36. The incident THF signals 34 may produce antenna currents that flow around the perimeter of radiating element arms 36. UTC PD 42 may use optical local oscillator signal LO1 (plus the optical phase shift S when applied), optical local oscillator signal LO2 (e.g., without modulation), and control signals V_{BIAS} (e.g., a bias voltage asserted at the second level) to convert the received THF signals 34 into intermediate frequency signals SIGIF that are output onto intermediate frequency signal path 44.

The frequency of intermediate frequency signals SIGIF may be equal to the frequency of THF signals 34 minus the difference between the frequency of optical local oscillator signal LO1 and the frequency of optical local oscillator signal LO2. As an example, intermediate frequency signals SIGIF may be at lower frequencies than THF signals 32 and 34 such as centimeter or millimeter wave frequencies between 10 GHz and 100 GHz, between 30 GHz and 80 GHz, around 60 GHz, etc. If desired, transceiver circuitry 26 (FIG. 1) may change the frequency of optical local oscillator signal LO1 and/or optical local oscillator signal LO2 when switching from transmission to reception or vice versa. UTC PD 42 may preserve the data modulation of THF signals 34 in intermediate signals SIGIF. A receiver in transceiver circuitry 26 (FIG. 1) may demodulate intermediate frequency signals SIGIF (e.g., after further downconversion) to recover the wireless data from THF signals 34. In another example, wireless circuitry 24 may convert intermediate frequency signals SIGIF to the optical domain before recovering the wireless data. In yet another example, intermediate frequency signal path 44 may be omitted and UTC PD 42 may convert THF signals 34 into the optical domain for subsequent demodulation and data recovery (e.g., in a sideband of the optical signal).

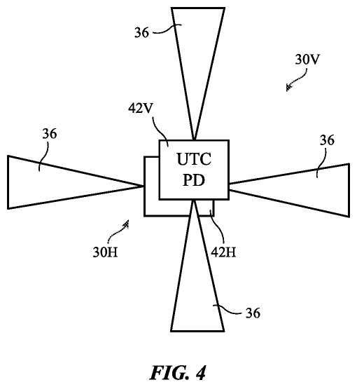

The antenna 30 of FIGS. 2 and 3 may support transmission of THF signals 32 and reception of THF signals 34 with a given polarization (e.g., a linear polarization such as a vertical polarization). If desired, wireless circuitry 24 (FIG. 1) may include multiple antennas 30 for covering different polarizations. FIG. 4 is a diagram showing one example of how wireless circuitry 24 may include multiple antennas 30 for covering different polarizations.

As shown in FIG. 4, the wireless circuitry may include a first antenna 30 such as antenna 30V for covering a first polarization (e.g., a first linear polarization such as a vertical polarization) and may include a second antenna 30 such as antenna 30H for covering a second polarization different from or orthogonal to the first polarization (e.g., a second linear polarization such as a horizontal polarization). Antenna 30V may have a UTC PD 42 such as UTC PD 42V coupled between a corresponding pair of radiating element arms 36. Antenna 30H may have a UTC PD 42 such as UTC PD 42H coupled between a corresponding pair of radiating element arms 36 oriented non-parallel (e.g., orthogonal) to the radiating element arms 36 in antenna 30V. This may allow antennas 30V and 30H to transmit THF signals 32 with respective (orthogonal) polarizations and may allow antennas 30V and 30H to receive THF signals 32 with respective (orthogonal) polarizations.

To minimize space within device 10, antenna 30V may be vertically stacked over or under antenna 30H (e.g., where UTC PD 42V partially or completely overlaps UTC PD 42H). In this example, antennas 30V and 30H may both be formed on the same substrate such as a rigid or flexible printed circuit board. The substrate may include multiple stacked dielectric layers (e.g., layers of ceramic, epoxy, flexible printed circuit board material, rigid printed circuit board material, etc.). The radiating element arms 36 in antenna 30V may be formed on a separate layer of the substrate than the radiating element arms 36 in antenna 30H or the radiating element arms 36 in antenna 30V may be formed on the same layer of the substrate as the radiating element arms 36 in antenna 30H. UTC PD 42V may be formed on the same layer of the substrate as UTC PD 42H or UTC PD 42V may be formed on a separate layer of the substrate than UTC PD 42H. UTC PD 42V may be formed on the same layer of the substrate as the radiating element arms 36 in antenna 30V or may be formed on a separate layer of the substrate as the radiating element arms 36 in antenna 30V. UTC PD 42H may be formed on the same layer of the substrate as the radiating element arms 36 in antenna 30H or may be formed on a separate layer of the substrate as the radiating element arms 36 in antenna 30H.

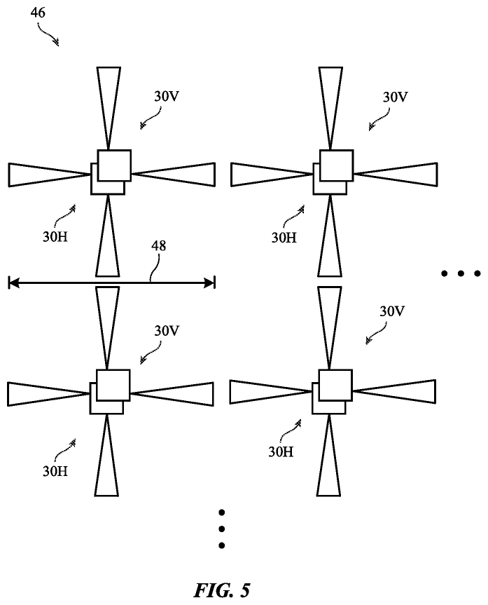

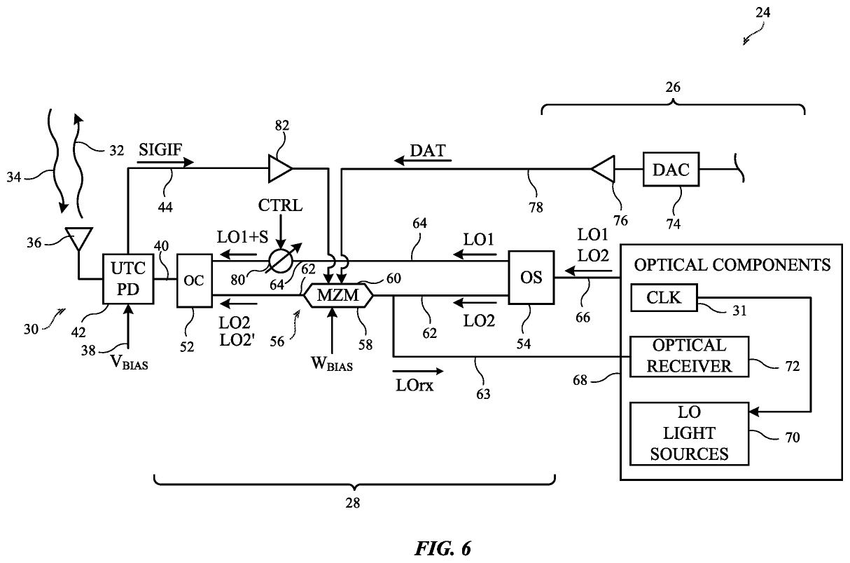

If desired, antennas 30 or antennas 30H and 30V of FIG. 4 may be integrated within a phased antenna array. FIG. 5 is a diagram showing one example of how antennas 30H and 30V may be integrated within a phased antenna array. As shown in FIG. 5, device 10 may include a phased antenna array 46 of stacked antennas 30H and 30V arranged in a rectangular grid of rows and columns. Each of the antennas in phased antenna array 46 may be formed on the same substrate. This is illustrative and non-limiting. In general, phased antenna array 46 (sometimes referred to as a phased array antenna) may include any desired number of antennas 30V and 30H (or non-stacked antennas 30) arranged in any desired pattern. Each of the antennas in phased antenna array 46 may be provided with a respective optical phase shift S (FIGS. 2 and 3) that configures the antennas to collectively transmit THF signals 32 and/or receive THF signals 34 that sum to form a signal beam of THF signals in a desired beam pointing direction. The beam pointing direction may be selected to point the signal beam towards external communications equipment, towards a desired external object, away from an external object, etc.

Phased antenna array 46 may occupy relatively little space within device 10. For example, each antenna 30V/30H may have a length 48 (e.g., as measured from the end of one radiating element arm to the opposing end of the opposite radiating element arm). Length 48 may be approximately equal to one-half the wavelength of THF signals 32 and 34. For example, length 48 may be as small as 0.5 mm or less. Each UTC-PD 42 in phased antenna array 46 may occupy a lateral area of 100 square microns or less. This may allow phased antenna array 46 to occupy very little area within device 10, thereby allowing the phased antenna array to be integrated within different portions of device 10 while still allowing other space for device components. The examples of FIGS. 2-5 are illustrative and non-limiting. In general, each antenna may have any desired antenna radiating element architecture.

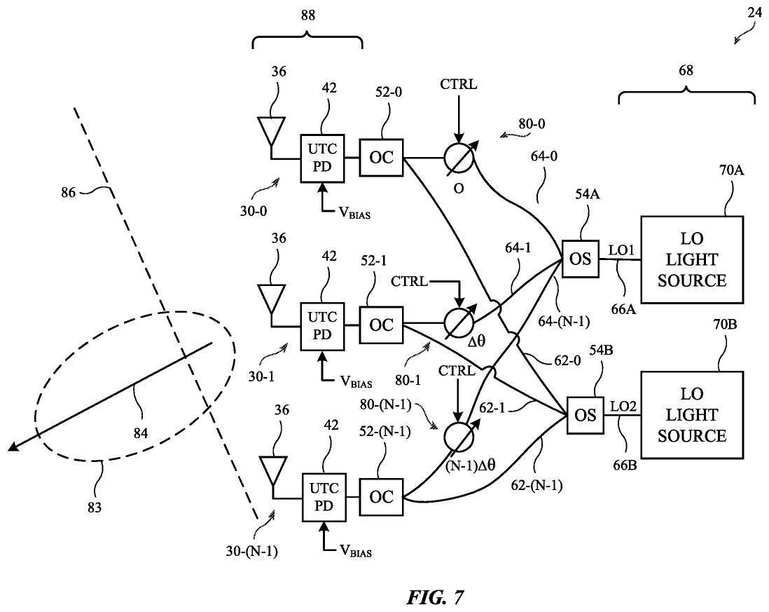

FIG. 6 is a circuit diagram showing one example of how a given antenna 30 and signal path 28 (FIG. 1) may be used to both transmit THF signals 32 and receive THF signals 34 based on optical local oscillator signals. In the example of FIG. 6, UTC PD 42 converts received THF signals 34 into intermediate frequency signals SIGIF that are then converted to the optical domain for recovering the wireless data from the received THF signals.

As shown in FIG. 6, wireless circuitry 24 may include transceiver circuitry 26 coupled to antenna 30 over signal path 28 (e.g., an optical signal path sometimes referred to herein as optical signal path 28). UTC PD 42 may be coupled between the radiating element arm(s) 36 of antenna 30 and signal path 28. Transceiver circuitry 26 may include optical components 68, amplifier circuitry such as power amplifier 76, and digital-to-analog converter (DAC) 74. Optical components 68 may include an optical receiver such as optical receiver 72 and optical local oscillator (LO) light sources (emitters) 70. LO light sources 70 may include two or more light sources (e.g., sources of electromagnetic energy, light, or light energy) such as laser light sources, laser diodes, optical phase locked loops, or other optical emitters that emit light (e.g., electromagnetic energy, light, or light energy that includes optical local oscillator signals LO1 and LO2) at respective wavelengths (e.g., visible, infrared, and/or ultraviolet wavelengths). If desired, LO light sources 70 may include a single light source and may include optical components for splitting the light emitted by the light source into different wavelengths. Signal path 28 may be coupled to optical components 68 over optical path 66. Optical path 66 may include one or more optical fibers and/or waveguides.

Signal path 28 may include an optical splitter such as optical splitter (OS) 54, optical paths such as optical path 64 and optical path 62, an optical combiner such as optical combiner (OC) 52, and optical path 40. Optical path 62 may be an optical fiber or waveguide. Optical path 64 may be an optical fiber or waveguide. Optical splitter 54 may have a first (e.g., input) port coupled to optical path 66, a second (e.g., output) port coupled to optical path 62, and a third (e.g., output) port coupled to optical path 64. Optical path 64 may couple optical splitter 54 to a first (e.g., input) port of optical combiner 52. Optical path 62 may couple optical splitter 54 to a second (e.g., input) port of optical combiner 52. Optical combiner 52 may have a third (e.g., output) port coupled to optical path 40.

An optical phase shifter such as optical phase shifter 80 may be (optically) interposed on or along optical path 64. An electro-optical modulator such as optical modulator 56 may be (optically) interposed on or along optical path 62. Optical modulator 56 may be, for example, a Mach-Zehnder modulator (MZM) and may therefore sometimes be referred to herein as MZM 56. MZM 56 includes a first optical arm (branch) 60 and a second optical arm (branch) 58 interposed in parallel along optical path 62. Propagating optical local oscillator signal LO2 along arms 60 and 58 of MZM 56 may, in the presence of a voltage signal applied to one or both arms, allow different optical phase shifts to be imparted on each arm before recombining the signal at the output of the MZM (e.g., where optical phase modulations produced on the arms are converted to intensity modulations at the output of MZM 56). When the voltage applied to MZM 56 includes wireless data, MZM 56 may modulate the wireless data onto optical local oscillator signal LO2. If desired, the phase shifting performed at MZM 56 may be used to perform beam forming/steering in addition to or instead of optical phase shifter 80. MZM 56 may receive one or more bias voltages WBIAS (sometimes referred to herein as bias signals WBIAS) applied to one or both of arms 58 and 60. Control circuitry 14 (FIG. 1) may provide bias voltage WBIAS with different magnitudes to place MZM 56 into different operating modes (e.g., operating modes that suppress optical carrier signals, operating modes that do not suppress optical carrier signals, etc.).

Intermediate frequency signal path 44 may couple UTC PD 42 to MZM 56 (e.g., arm 60). An amplifier such as low noise amplifier 82 may be interposed on intermediate frequency signal path 44. Intermediate frequency signal path 44 may be used to pass intermediate frequency signals SIGIF from UTC PD 42 to MZM 56. DAC 74 may have an input coupled to up-conversion circuitry, modulator circuitry, and/or baseband circuitry in a transmitter of transceiver circuitry 26. DAC 74 may receive digital data to transmit over antenna 30 and may convert the digital data to the analog domain (e.g., as data DAT). DAC 74 may have an output coupled to transmit data path 78. Transmit data path 78 may couple DAC 74 to MZM 56 (e.g., arm 60). Each of the components along signal path 28 may allow the same antenna 30 to both transmit THF signals 32 and receive THF signals 34 (e.g., using the same components along signal path 28), thereby minimizing space and resource consumption within device 10.

LO light sources 70 may produce (emit) optical local oscillator signals LO1 and LO2 (e.g., at different wavelengths that are separated by the wavelength of THF signals 32/34). Optical components 68 may include lenses, waveguides, optical couplers, optical fibers, and/or other optical components that direct the emitted optical local oscillator signals LO1 and LO2 towards optical splitter 54 via optical path 66. Optical splitter 54 may split the optical signals on optical path 66 (e.g., by wavelength) to output optical local oscillator signal LO1 onto optical path 64 while outputting optical local oscillator signal LO2 onto optical path 62.

Control circuitry 14 (FIG. 1) may provide phase control signals CTRL to optical phase shifter 80. Phase control signals CTRL may control optical phase shifter 80 to apply optical phase shift S to the optical local oscillator signal LO1 on optical path 64. Phase shift S may be selected to steer a signal beam of THF signals 32/34 in a desired pointing direction. Optical phase shifter 80 may pass the phase-shifted optical local oscillator signal LO1 (denoted as LO1+S) to optical combiner 52. Signal beam steering is performed in the optical domain (e.g., using optical phase shifter 80) rather than in the THF domain because there are no satisfactory phase shifting circuit components that operate at frequencies as high as the frequencies of THF signals 32 and 34. Optical combiner 52 may receive optical local oscillator signal LO2 over optical path 62. Optical combiner 52 may combine optical local oscillator signals LO1 and LO2 onto optical path 40, which directs the optical local oscillator signals onto UTC PD 42 for use during signal transmission or reception.

During transmission of THF signals 32, DAC 74 may receive digital wireless data (e.g., data packets, frames, symbols, etc.) for transmission over THF signals 32. DAC 74 may convert the digital wireless data to the analog domain and may output (transmit) the data onto transmit data path 78 as data DAT (e.g., for transmission via antenna 30). Power amplifier 76 may amplify data DAT. Transmit data path 78 may pass data DAT to MZM 56 (e.g., arm 60). MZM 56 may modulate data DAT onto optical local oscillator signal LO2 to produce modulated optical local oscillator signal LO2′ (e.g., an optical local oscillator signal at the frequency/wavelength of optical local oscillator signal LO2 but that is modulated to include the data identified by data DAT). Optical combiner 52 may combine optical local oscillator signal LO1 with modulated optical local oscillator signal LO2′ at optical path 40.

Optical path 40 may illuminate UTC PD 42 with (using) optical local oscillator signal LO1 (e.g., with the phase shift S applied by optical phase shifter 80) and modulated optical local oscillator signal LO2′. Control circuitry 14 (FIG. 1) may apply a control signal V_{BIAS} to UTC PD 42 that configures antenna 30 for the transmission of THF signals 32. UTC PD 42 may convert optical local oscillator signal LO1 and modulated optical local oscillator signal LO2′ into antenna currents on radiating element arm(s) 36 at the frequency of THF signals 32 (e.g., while programmed for transmission using control signal V_{BIAS}). The antenna currents on radiating element arm(s) 36 may radiate THF signals 32. The frequency of THF signals 32 is given by the difference in frequency between optical local oscillator signal LO1 and modulated optical local oscillator signal LO2′. Control signals V_{BIAS} may control UTC PD 42 to preserve the modulation from modulated optical local oscillator signal LO2′ in the radiated THF signals 32. External equipment that receives THF signals 32 will thereby be able to extract data DAT from the THF signals 32 transmitted by antenna 30.

During reception of THF signals 34, MZM 56 does not modulate any data onto optical local oscillator signal LO2. Optical path 40 therefore illuminates UTC PD 42 with optical local oscillator signal LO1 (e.g., with phase shift S) and optical local oscillator signal LO2. Control circuitry 14 (FIG. 1) may apply a control signal V_{BIAS} (e.g., a bias voltage) to UTC PD 42 that configures antenna 30 for the receipt of THF signals 32. UTC PD 42 may use optical local oscillator signals LO1 and LO2 to convert the received THF signals 34 into intermediate frequency signals SIGIF output onto intermediate frequency signal path 44 (e.g., while programmed for reception using bias voltage V_{BIAS}). Intermediate frequency signals SIGIF may include the modulated data from the received THF signals 34. Low noise amplifier 82 may amplify intermediate frequency signals SIGIF, which are then provided to MZM 56 (e.g., arm 60). MZM 56 may convert intermediate frequency signals SIGIF to the optical domain as optical signals LOrx (e.g., by modulating the data in intermediate frequency signals SIGIF onto one of the optical local oscillator signals) and may pass the optical signals to optical receiver 72 in optical components 68, as shown by arrow 63 (e.g., via optical paths 62 and 66 or other optical paths). Control circuitry 14 (FIG. 1) may use optical receiver 72 to convert optical signals LOrx to other formats and to recover (demodulate) the data carried by THF signals 34 from the optical signals. In this way, the same antenna 30 and signal path 28 may be used for both the transmission and reception of THF signals while also performing beam steering operations.

The example of FIG. 6 in which intermediate frequency signals SIGIF are converted to the optical domain is illustrative and non-limiting. If desired, transceiver circuitry 26 may receive and demodulate intermediate frequency signals SIGIF without first passing the signals to the optical domain. For example, transceiver circuitry 26 may include an analog-to-digital converter (ADC), intermediate frequency signal path 44 may be coupled to an input of the ADC rather than to MZM 56, and the ADC may convert intermediate frequency signals SIGIF to the digital domain. As another example, intermediate frequency signal path 44 may be omitted and control signals V_{BIAS} may control UTC PD 42 to directly sample THF signals 34 with optical local oscillator signals LO1 and LO2 to the optical domain. As an example, UTC PD 42 may use the received THF signals 34 and control signals V_{BIAS} to produce an optical signal on optical path 40. The optical signal may have an optical carrier with sidebands that are separated from the optical carrier by a fixed frequency offset (e.g., 30-100 GHz, 60 GHz, 50-70 GHz, 10-100 GHz, etc.). The sidebands may be used to carry the modulated data from the received THF signals 34. Signal path 28 may direct (propagate) the optical signal produced by UTC PD 42 to optical receiver 72 in optical components 68 (e.g., via optical paths 40, 64, 62, 66, 63, and/or other optical paths). Control circuitry 14 (FIG. 1) may use optical receiver 72 to convert the optical signal to other formats and to recover (demodulate) the data carried by THF signals 34 from the optical signal (e.g., from the sidebands of the optical signal).

If desired, optical components 68 may include clocking circuitry such as clocking circuitry 31. Clocking circuitry 31 may include one or more electro-optical phase-locked loops (OPLLs), frequency locked loops (FLLs), and self-injection locked (locking) loops. As shown in FIG. 6, clocking circuitry 31 may be used to control and clock LO light sources 70 and/or to clock any other desired hardware in device 10 (e.g., clocking circuitry 31 need not be located in transceiver 26 and may, in general, be located elsewhere in device 10). LO light sources 70 may, for example, generate optical LO signals (e.g., optical local oscillator signals LO1 and LO2) that are phase-locked, self-injection locked, and/or frequency-locked with respect to each other using clocking circuitry 31.

FIG. 7 is a circuit diagram showing one example of how multiple antennas 30 may be integrated into a phased antenna array 88 that conveys THF signals over a corresponding signal beam. In the example of FIG. 7. MZMs 56, intermediate frequency signal paths 44, data paths 78, and optical receiver 72 of FIG. 6 have been omitted for the sake of clarity. Each of the antennas in phased antenna array 88 may alternatively sample received THF signals directly into the optical domain or may pass intermediate frequency signals SIGIF to ADCs in transceiver circuitry 26.

As shown in FIG. 7, phased antenna array 88 includes N antennas 30 such as a first antenna 30-0, a second antenna 30-1, and an Nth antenna 30-(N−1). Each of the antennas 30 in phased antenna array 88 may be coupled to optical components 68 via a respective optical signal path (e.g., optical signal path 28 of FIG. 6). Each of the N signal paths may include a respective optical combiner 52 coupled to the UTC PD 42 of the corresponding antenna 30 (e.g., the UTC PD 42 in antenna 30-0 may be coupled to optical combiner 52-0, the UTC PD 42 in antenna 30-1 may be coupled to optical combiner 52-1, the UTC PD 42 in antenna 30-(N−1) may be coupled to optical combiner 52-(N−1), etc.). Each of the N signal paths may also include a respective optical path 62 and a respective optical path 64 coupled to the corresponding optical combiner 52 (e.g., optical paths 64-0 and 62-0 may be coupled to optical combiner 52-0, optical paths 64-1 and 62-1 may be coupled to optical combiner 52-1, optical paths 64-(N−1) and 62-(N−1) may be coupled to optical combiner 52-(N−1), etc.).

Optical components 68 may include LO light sources 70 such as a first LO light source 70A and a second LO light source 70B. The optical signal paths for each of the antennas 30 in phased antenna array 88 may share one or more optical splitters 54 such as a first optical splitter 54A and a second optical splitter 54B. LO light source 70A may generate (e.g., produce, emit, transmit, etc.) first optical local oscillator signal LO1 and may provide first optical local oscillator signal LO1 to optical splitter 54A via optical path 66A. Optical splitter 54A may distribute first optical local oscillator signal LO1 to each of the UTC PDs 42 in phased antenna array 88 over optical paths 64 (e.g., optical paths 64-0, 64-1, 64-(N−1), etc.). Similarly, LO light source 70B may generate (e.g., produce, emit, transmit, etc.) second optical local oscillator signal LO2 and may provide second optical local oscillator signal LO2 to optical splitter 54B via optical path 66B. Optical splitter 54B may distribute second optical local oscillator signal LO2 to each of the UTC PDs 42 in phased antenna array 88 over optical paths 62 (e.g., optical paths 62-0, 62-1, 62-(N−1), etc.).

A respective optical phase shifter 80 may be interposed along (on) each optical path 64 (e.g., a first optical phase shifter 80-0 may be interposed along optical path 64-0, a second optical phase shifter 80-1 may be interposed along optical path 64-1, an Nth optical phase shifter 80-(N−1) may be interposed along optical path 64-(N−1), etc.). Each optical phase shifter 80 may receive a control signal CTRL that controls the phase S provided to optical local oscillator signal LO1 by that optical phase shifter (e.g., first optical phase shifter 80-0 may impart an optical phase shift of zero degrees/radians to the optical local oscillator signal LO1 provided to antenna 30-0, second optical phase shifter 80-1 may impart an optical phase shift of Δϕ to the optical local oscillator signal LO1 provided to antenna 30-1, Nth optical phase shifter 80-(N−1) may impart an optical phase shift of (N−1)Δϕ to the optical local oscillator signal LO1 provided to antenna 30-(N−1), etc.). By adjusting the phase S imparted by each of the N optical phase shifters 80, control circuitry 14 (FIG. 1) may control each of the antennas 30 in phased antenna array 88 to transmit THF signals 32 and/or to receive THF signals 34 within a formed signal beam 83. Signal beam 83 may be oriented in a particular beam pointing direction (angle) 84 (e.g., the direction of peak gain of signal beam 83). The THF signals conveyed by phased antenna array 88 may have wavefronts 86 that are orthogonal to beam pointing direction 84. Control circuitry 14 may adjust beam pointing direction 84 over time to point towards external communications equipment or an external object or to point away from external objects, as examples.

Phased antenna array 88 may be operable in an active mode in which the array transmits and/or receives THF signals using optical local oscillator signals LO1 and LO2 (e.g., using phase shifts provided to each antenna element to steer signal beam 83). If desired, phased antenna array 88 may also be operable in a passive mode in which the array does not transmit or receive THF signals. Instead, in the passive mode, phased antenna array 88 may be configured to form a passive reflector that reflects THF signals or other electromagnetic waves incident upon device 10. In the passive mode, the UTC PDs 42 in phased antenna array 88 are not illuminated by optical local oscillator signals LO1 and LO2 and transceiver circuitry 26 performs no modulation/demodulation, mixing, filtering, detection, modulation, and/or amplifying of the incident THF signals.

Devices with THF signaling capabilities such as device 10 are particularly sensitive to phase noise in clock signals (e.g., because the clocking circuitry consumes a relatively high amount of power and chip area for THF frequencies). To minimize phase noise, processing operations in device 10 may be clocked using clocking circuitry 31. Examples in which THF communications using transceiver 26 (FIG. 1) are clocked using clocking circuitry 31 are described herein as an example. This is illustrative and non-limiting. In general, clocking circuitry 31 may be used to clock any desired processing operations in device 10 (e.g., high speed digital interface operations, processor computations, sensing, automotive, input/output operations, communications at frequencies lower than 100 GHz such as millimeter/centimeter wave frequencies or frequencies less than 10 GHz, etc.).

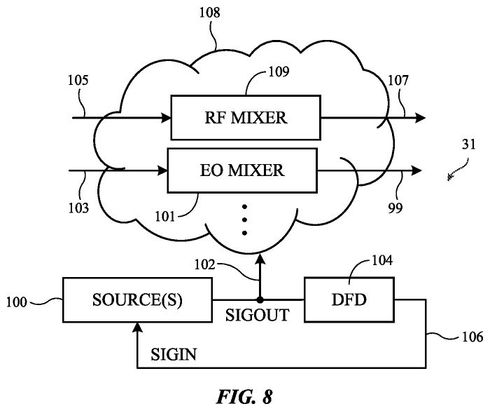

To minimize phase noise in the clock signals generated by clocking circuitry 31, clocking circuitry 31 may include a digital frequency discriminator coupled between an output and an input of a signal source. FIG. 8 is a circuit diagram showing how clocking circuitry 31 may include a digital frequency discriminator.

As shown in FIG. 8, clocking circuitry 31 may include one or more signal sources such as signal source 100. Signal source 100 may output clock signal SIGOUT at its output. Clocking circuitry 31 may output clock signal SIGOUT at output path 102. Signal source 100 may also have an input (e.g., a control input, a DC offset input, etc.) coupled to the output of signal source 100 over loop path 106. Signal source 100 may include an oscillator (e.g., a voltage controlled oscillator, a digitally controlled oscillator, a crystal oscillator, etc.) that generates clock signal SIGOUT at radio frequencies or intermediate frequencies and/or may include one or more light sources (e.g., LO sources 70 of FIGS. 6 and 7 such as one or more lasers) that generates clock signal SIGOUT at optical wavelengths (e.g., as an optical local oscillator signal).

Output path 102 may be coupled to a clock input of one or more components 108 on device 10. Clocking circuitry 31 may provide clock signal SIGOUT to components 108 to clock components 108. Components 108 may be used in conveying wireless data over antennas 30 (FIG. 1) or may be used to perform other functions. As one example, components 108 may include a radio (RF) mixer 109 disposed on a radio-frequency transmission line for a corresponding antenna 30 (FIG. 1). Radio mixer 109 may receive an input signal 105 and may mix (e.g., downconvert or upconvert) input signal 105 with clock signal SIGOUT to generate output signal 107. Radio mixer 109 may receive input signal 105 from antenna 30, baseband circuitry, another mixer, etc. Output signal 107 may be provided to baseband circuitry, antenna 30, another mixer, etc. Input signal 105 may be a radio-frequency signal, an intermediate frequency signal, or a baseband signal, as examples. Output signal 107 may be a baseband signal, an intermediate frequency signal, or a radio-frequency signal.

Additionally or alternatively, components 108 may include an EO mixer 101. EO mixer 101 may receive an input signal 103 and may mix (e.g., upconvert or downconvert) input signal 103 with clock signal SIGOUT to generate output signal 99. EO mixer 101 may include an electro-optical modulator (e.g., an MZM modulator), a photodiode (e.g., a UTC-PD), plasmonic components, or any other desired electro-optical components. Input signal 103 may be a THF antenna current or an optical LO signal, for example. Output signal 99 may be a THF antenna current or an optical LO signal. In other words, EO mixer 101 may use clock signal SIGOUT (e.g., an optical LO signal) to upconvert or downconvert input signal 103 (e.g., to or from optical frequencies, radio frequencies, etc.). Components 108 may include any other desired components clocked using clock signal SIGOUT.

If desired, a frequency discriminator may be disposed on loop path 106. The frequency discriminator may be used to measure phase noise in clock signal SIGOUT for use in adjusting signal source 100 to mitigate the measured phase noise (e.g., via signals provided to the input of signal source 100 over loop path 106). The frequency discriminator may include a delay line, a phase shifter, and a mixer that are used to mix a delayed input signal with a 90-degree phase-shifted version of itself, converting phase error from the input signal into a measurable voltage.

In some implementations, an analog frequency discriminator is disposed on loop path 106. However, analog frequency discriminators can be challenging to implement and can consume an excessive amount of space to produce a sufficiently stable and lengthy delay. In addition, it can be difficult to maintain a precise 90-degree phase shift between paths of the discriminator as required for maximum efficiency and measurement reliability. To mitigate these issues, clocking circuitry 31 may include a digital frequency discriminator (DFD) 104 disposed on loop path 106. DFD 104 is a self-referencing frequency discriminator and may therefore sometimes be referred to herein as self-referencing DFD 104 or self-referencing frequency discriminator 104.

DFD 104 may measure the phase noise of clock signal SIGOUT (e.g., in the digital domain) and may control signal source 100 based on the measured phase noise. For example, DFD 104 may generate a control signal SIGIN based on clock signal SIGOUT. Control signal SIGIN may be based on or may represent the phase noise of clock signal SIGOUT as measured by DFD 104. DFD 104 may provide control signal SIGIN to the input of signal source 100 over loop path 106 (e.g., control signal SIGIN may be fed back to signal source 100). Control signal SIGIN may dynamically control or adjust signal source 100 to re-generate clock signal SIGOUT in a manner that minimizes, reverses, or mitigates the phase noise as measured from clock signal SIGOUT (e.g., control signal SIGIN may be used to phase-lock signal source 100). Multiple iterations around loop path 106 may be performed until a stable and low phase noise clock signal SIGOUT is provided at output path 102. If desired, clocking circuitry 31 may include multiple signal sources 100, some or all of the signal sources may have a corresponding loop path 106, and some or all of the loop paths may have a DFD such as DFD 104.

DFD 104 may be implemented using a set of digital logic gates. The logic gates of DFD 104 may, for example, be fabricated in a semiconductor substrate using a deep sub-micron complementary metal-oxide-semiconductor (CMOS) process. This may allow the components of DFD 104 to be implemented in the digital domain using as low a size and as low a power consumption as possible. As such, DFD 104 may help to mitigate phase noise for signal source 100 while consuming as little space in device 10 as possible and while maintaining a precise 90-degree phase shift as required for maximum efficiency and measurement reliability.

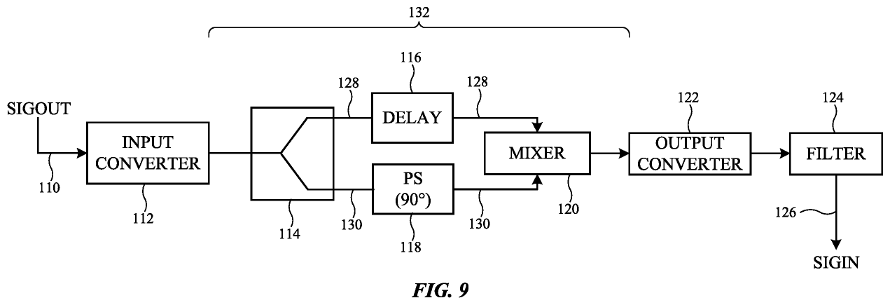

FIG. 9 is a circuit diagram of DFD 104. As shown in FIG. 9, DFD 104 may include digital circuitry 132 coupled between an input 110 and an output 126 of DFD 104. When DFD 104 is disposed on loop path 106 of FIG. 8, input 110 may be coupled to the output of signal source 100 whereas output 126 is coupled to the input of signal source 100.

DFD 104 may also include an input converter 112 and an output converter 122. Input converter 112 may be coupled between input 110 and digital circuitry 132. Output converter 122 may be coupled between output 126 and digital circuitry 132. Input converter 112 and output converter 122 may be used to convert signals between the analog domain (e.g., at input 100 and output 126) and the digital domain (e.g., at digital circuitry 132).

Digital circuitry 132 may include a signal splitter 114, digital delay circuitry such as delay circuitry 116, a digital phase shifter such as phase shifter (PS) 118, and a digital mixer such as mixer 120. Signal splitter 114, delay circuitry 116, phase shifter 118, and mixer 120 may be implemented using sets of digital logic gates that are, for example, fabricated in a semiconductor substrate using a deep sub-micron complementary metal-oxide-semiconductor (CMOS) process. Input converter 112 may have an input coupled to input 110 and may have an output coupled to the input of signal splitter 114. Signal splitter 114 may have a first output coupled to a first input of mixer 120 over digital path 128. Signal splitter 114 may have a second output coupled to a second input of mixer 120 over digital path 130. Delay circuitry 116 may be disposed on digital path 128. Delay circuitry 116 may sometimes be referred to herein as digital delay circuitry 116 or simply as digital delay 116. The input of delay circuitry 116 may be coupled to the first output of signal splitter 114. The output of delay circuitry 116 may be coupled to the first input of mixer 120. Phase shifter 118 may be disposed on digital path 130. The input of phase shifter 118 may be coupled to the second output of signal splitter 114. The output of phase shifter 118 may be coupled to the second input of mixer 120.

If desired, DFD 104 may include a filter such as filter 124 (e.g., a low pass filter or other type of filter). The output of mixer 120 may be coupled to the input of output converter 122. The output of output converter 122 may be coupled to the input of filter 124. The output of filter 124 may be coupled to output 126. Filter 124 may be omitted if desired. Additional components (not shown) may be disposed between input 110 and output 126 if desired.

DFD 104 may receive an input signal at input 110. DFD 104 may measure the phase noise of the input signal and may output control signal SIGIN based on the measured phase noise (e.g., control signal SIGIN may identify, reflect, or represent the measured phase noise). During transmission of clock signal SIGOUT by signal source 100 (FIG. 8), clock signal SIGOUT forms the input signal received at input 110. Input converter 112 may convert clock signal SIGOUT from the analog domain or the time domain into the digital domain. As a first example, input converter 112 may include a time-to-digital converter (TDC) that converts clock signal SIGOUT from the time domain to the digital domain (e.g., as a digital signal). For example, the TDC may receive a series of pulses of clock signal SIGOUT and may output a digital signal indicative of the times at which each pulse in the series of pulses was received. As a second example, input converter 112 may include an analog-to-digital converter (ADC) that converts clock signal SIGOUT from the analog domain to the digital domain (e.g., a digital signal or waveform corresponding to the analog clock signal SIGOUT received at input 110). The ADC may be implemented using any desired ADC architecture.

Signal splitter 114 may split the digital signal output by input converter 112 between digital path 128 and digital path 130. Delay circuitry 116 may add a digital time delay to the digital signal on digital path 128 to generate a delayed digital signal. The time delay may be sufficiently long to decorrelate the signals to reduce phase noise. Delay circuitry 116 may provide the delayed digital signal to the first input of mixer 120. Phase shifter 118 on digital path 130 may add a digital phase shift to the digital signal on digital path 130 to generate a phase shifted digital signal. Phase shifter 118 may, for example, add a 90-degree phase shift to the digital signal on digital path 130. Phase shifter 118 may provide the phase shifted digital signal to the second input of mixer 120.

Mixer 120 is a digital mixer and may mix the delayed digital signal with the phase shifted digital signal (in the digital domain) to generate a digital error signal. In other words, mixer 120 may generate the digital error signal by mixing a delayed digital version of clock signal SIGOUT with a 90-degree phase shifted digital version of clock signal SIGOUT. The digital error signal may represent the phase error of clock signal SIGOUT (e.g., mixer 120 may serve as a phase detector that converts phase error into voltage).

Mixer 120 may provide the digital error signal to output converter 122. Output converter 122 may convert the digital error signal from the digital domain back into the time domain or the analog domain (e.g., as a time or analog domain representation of the phase error of clock signal SIGOUT). As a first example, output converter 122 may include a digital-to-time converter (DTC) that converts the digital error signal from the digital domain to the time domain (e.g., as control signal SIGIN). The DTC may generate a time domain signal by programming the edges of a digital signal pulse to have a selected timing, for example. The DTC may additionally or alternatively set (program) the frequency, delay, duty cycle, and/or per-clock interval of the signal pulse.

As a second example, output converter 122 may include a digital-to-analog converter (DAC) that converts the digital error signal from the digital domain to the analog domain (e.g., as control signal SIGIN). The DAC may be implemented using any desired DAC architecture. As a third example, output converter 122 may be omitted and DFD 104 may provide control signal SIGIN to the input of signal source 100 in the digital domain (e.g., control signal SIGIN may be a digital signal).

If desired filter 124 may filter control signal SIGIN (e.g., to remove noise or unwanted signals or artifacts, to smooth the signal, etc.). DFD 104 may feed control signal SIGIN into the input of signal source 100 (FIG. 8) to control the signal source to generate clock signal SIGOUT in a manner that mitigates, reverses, or minimizes the detected phase error represented by control signal SIGIN.

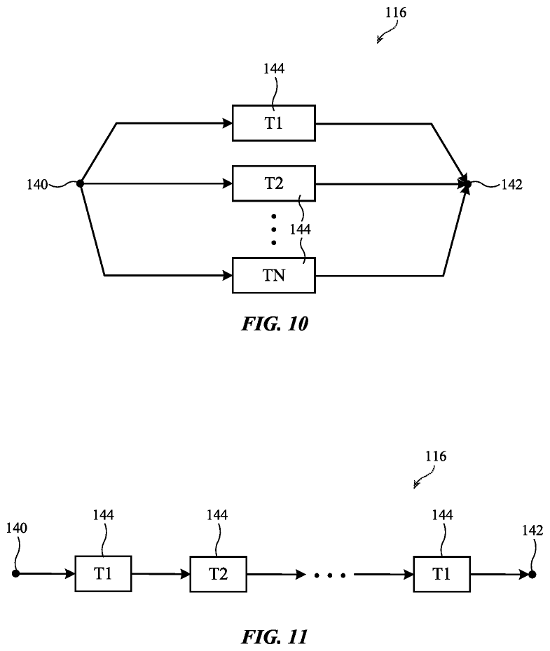

If desired, delay circuitry 116 may include multiple delay stages (e.g., one or more digital delays or paths) to help smooth the phase noise of clock signal SIGOUT. FIG. 10 is a circuit diagram showing one example of how delay circuitry 116 may include multiple delay stages coupled in parallel between signal splitter 114 and mixer 120.

As shown in FIG. 10, delay circuitry 116 may have an input terminal 140 (e.g., a signal splitter) coupled to the first output of signal splitter 114 and an output terminal 142 (e.g., a signal or power combiner) coupled to the first input of mixer 120 (FIG. 9). Delay circuitry 116 may include a set of N digital delay circuits 144 (sometimes referred to herein as digital delay stages 144) coupled in parallel between input terminal 140 and output terminal 142. Each digital delay circuit 144 may include one or more buffers, filters, or other digital delay components that impart a respective digital delay T (e.g., T1, T2, TN, etc.) to the digital signal received from the first output of signal splitter 114. Each of the delayed signals may be combined at output terminal 142 and provided to the first input of mixer 128.

FIG. 11 is a circuit diagram showing one example of how delay circuitry 116 may include multiple delay stages coupled in series between signal splitter 114 and mixer 120. As shown in FIG. 11. digital delay circuits 144 coupled in series between input terminal 140 and output terminal 142. The examples of FIGS. 10 and 11 are illustrative and non-limiting. Delay circuits 144 may be coupled together in series, in parallel, and/or in any other desired manner between input terminal 140 and output terminal 142 (e.g., the configurations of FIGS. 10 and 11 may be combined). The delays T imparted by delay circuits 144 may be individually selected to minimize side effects such as spurs to the signal. Implementing delay circuitry 116 in the digital domain may consume significantly less space in device 10 than in implementations where a frequency discriminator is provided with optical delays (e.g., spools of optical fiber that can be several km in length).

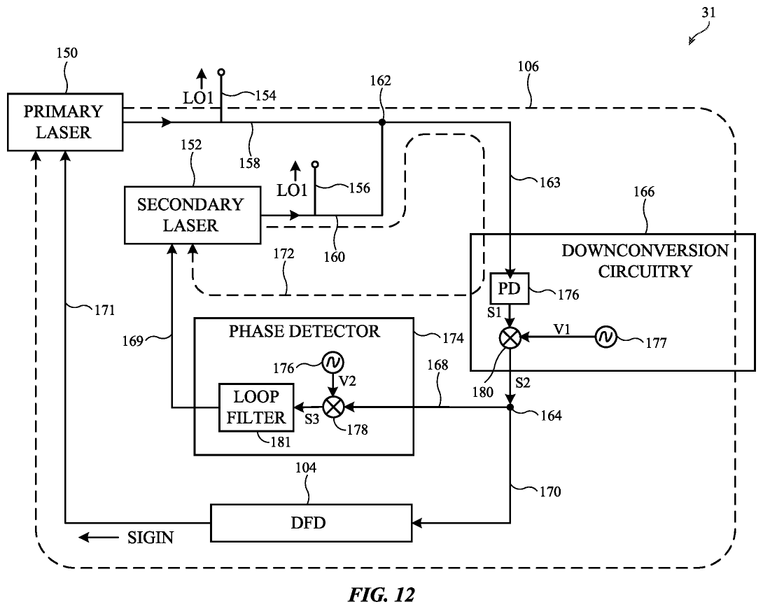

DFD 104 of FIGS. 8 and 9 may be used to minimize phase noise in clock signal SIGOUT regardless of whether clock signal SIGOUT is at radio frequencies or optical frequencies. FIG. 12 is a circuit diagram showing one example of how DFD 104 may be used to minimize phase noise when clock signal SIGOUT is at optical frequencies.

As shown in FIG. 12, clocking circuitry 31 may be used to clock or control a first light source such as primary laser 150 (e.g., from LO light sources 70 of FIG. 6) and a second light source such as secondary laser 152 (e.g., from LO light sources 70 of FIG. 6). Primary laser 150 may form signal source 100 for DFD 104 (FIG. 8). Secondary laser 152 may have an output coupled to optical path 160. An output terminal 156 of clocking circuitry 31 may be coupled to optical path 160. Primary laser 150 may have an output coupled to optical path 158. An output terminal 154 of clocking circuitry 31 may be coupled to optical path 158. Optical paths 158 and 160 may be coupled to inputs of optical combiner 162.

Optical combiner 162 may have an output coupled to the input of signal splitter 164 over optical path 163. Signal splitter 164 may have a first output coupled to the input phase detector 174 over path 168. Phase detector 174 may have an output coupled to the input of secondary laser 152 over path 169. Signal splitter 164 may have a second output coupled to the input of DFD 104 over path 170. The output of DFD 104 may be coupled to the input of primary laser 150 over path 171. Optical paths 158, 160, and 163 and paths 168, 170, 169, and 171 may each include one or more optical waveguides, optical splitters, optical combiners, optical switches, optical lenses, optical prisms, optical beam splitters, and/or optical couplers and/or electrical paths (e.g., conductive traces, conductive wirings, radio-frequency transmission line structures, etc.). Output terminals 154 and 156 may be coupled to a UTC PD 42 over respective optical paths 64 and 62 (FIG. 6), for example.

If desired, downconversion circuitry 166 may be disposed on optical path 163 between optical splitter 162 and signal splitter 164. Downconversion circuitry 166 may include a photodetector 176 (e.g., a UTC PD or other photodiode), a mixer 180, and a signal source 177. Photodetector 176 may have an input coupled to optical path 163. Mixer 180 may have a first input coupled to the output of photodetector 176. Signal source 177 may provide a reference signal V1 to a second input of mixer 180. Mixer 180 may have an output coupled to the input of signal splitter 164.

Phase detector may have a mixer 178, a signal source 176, and a loop filter 181. Mixer 178 may have a first input coupled to path 168 and a second input coupled to signal source 176. Signal source 176 may provide a reference signal V2 to the second input of mixer 178. Mixer 178 may have an output coupled to the input of loop filter 181. The output of loop filter 181 may be coupled to the input of secondary laser 152 over path 169.

During operation, primary laser 150 may emit first optical local oscillator signal LO1 on optical path 158. Secondary laser 152 may emit second optical local oscillator signal LO2 on optical path 118. Output terminals 154 and 156 may transmit optical local oscillator signals LO1 and LO2, respectively, to clock other components in device 10 (e.g., components 108 of FIG. 8). In implementations where clocking circuitry 31 is used to clock THF communications using transceiver 26 (FIG. 1), output terminal 154 may be coupled to optical path 64 and output terminal 156 may be coupled to optical path 62 of FIG. 6, for example.

Clocking circuitry 31 may include multiple control/feedback loops that are used to minimize phase noise in the optical LO signals provided to output terminals 154 and 156. As shown in FIG. 12, clocking circuitry 31 may include at least a first loop path 106 around primary laser 150 and a second loop path 172 around secondary laser 152. At least part of loop path 172 may form part of loop path 106. For example, the output of primary laser 150, optical path 158, optical path 163, downconversion circuitry 166, path 170, DFD 104, and path 171 may form loop path 106 (e.g., a frequency-locked loop (FLL), a phase-locked loop (PLL), etc.). The output of secondary laser 152, optical path 160, optical path 163, downconversion circuitry 166, path 168, phase detector 174, and path 169 may form loop path 172.

Primary laser 150 may emit first optical local oscillator signal LO1 at a first optical frequency F1 (e.g., 200,000 GHz). Secondary laser 152 may emit second optical local oscillator signal LO2 at a second optical frequency F2 (e.g., 200,300 GHz). Second optical frequency F2 may be offset from first optical frequency F1 by a frequency offset Y (e.g., Y=200,300-200,000=300 GHz). Optical frequencies F1 and F2 and thus frequency offset Y may be selected so that frequency offset Y is a radio frequency such as the frequency of the THF signals 32 to be transmitted and/or the THF signals 34 to be received by the antenna 36 fed using optical local oscillator signals LO1 and LO2 (e.g., 300 GHz, 100-1000 GHz, etc.).

In implementations where clocking circuitry 31 includes downconversion circuitry 166, downconversion circuitry 166 may downconvert the optical signals to frequencies that are easier to process than optical frequencies (e.g., radio frequencies). For example, optical local oscillator signals LO1 and LO2 may illuminate photodetector 176. Photodetector 176 may generate corresponding radio-frequency signals S1 (e.g., at a frequency given by the difference between the frequencies of optical local oscillator signals LO1 and LO2). Mixer 180 may mix radio-frequency signals S1 with reference signal V1 to produce signals S2 (e.g., at lower frequencies than radio-frequency signals S1).

Signal splitter 164 may provide signals S2 to phase detector 174 over path 168 and to DFD 104 over path 170 (e.g., as clock signal SIGOUT of FIGS. 8 and 9). DFD 104 may generate control signal SIGIN based on signal S2. DFD 104 may provide control signal SIGIN to the input of primary laser 150 over path 171. Primary laser 150 may adjust local oscillator signal LO1 in a manner that mitigates the phase error identified by control signal SIGIN and/or that frequency locks local oscillator signal LO1.

Once primary laser 150 has been locked by control signal SIGIN, phase detector 174 may generate a phase signal S3 by mixing reference signal V2 with signal S2 at mixer 178. Loop filter 181 may filter phase signal S3. Phase detector 174 may provide phase signal S3 to secondary laser 152 over path 169. Secondary laser 152 may adjust optical local oscillator signal LO2 based on phase signal S3 (e.g., in a manner that locks the phase of optical local oscillator signal LO2 to the phase of optical local oscillator signal LO1 after one or more iterations around loop paths 106 and/or 172). This may configure fluctuations (e.g., phase variations) in secondary laser 152 and thus optical local oscillator signal LO2 to tightly follow any fluctuations (e.g., phase variations) in primary laser 150 and thus optical local oscillator signal LO1, thereby configuring the separation in frequency and phase between optical local oscillator signal LO1 and optical local oscillator signal LO2 to be constant over time. This may serve to allow the components clocked using optical local oscillator signals LO1 and LO2 to exhibit extremely stable performance over time (e.g., insensitive to phase noise and jitter).

The example of FIG. 12 is illustrative and non-limiting. If desired, one or more additional phase-locked loops (PLLs), frequency locked-loops (FLLs), and/or self-injection locking loops (not shown) may be coupled around one or both lasers to further lock optical local oscillator signals LO1 and LO2 together (e.g., to perform coarse and then fine laser tuning until the clocking circuitry is locked). DFD 104 may be disposed on some or all of any of these loops. While described herein as lasers, primary laser 150 and secondary laser 152 may be any desired light sources/emitters. Lasers 150 and 152 may form LO light sources 70 of FIG. 7 and/or may respectively form LO light sources 70A and 70B of FIG. 7, for example. Primary laser 150 may sometimes also be referred to as a leader laser whereas secondary laser 152 is sometimes also referred to as a follower laser.

Control signal SIGIN may, for example, be provided to a control terminal or offset terminal of primary laser 150 that controls primary laser 150 to adjust the phase and/or frequency of the emitted optical local oscillator signal LO1. In implementations where control signal SIGIN remains in the digital domain (e.g., when output converter 122 of FIG. 9 is omitted), path 171 may include a set of digital control lines provided to primary laser 150 and that are either active or inactive. Some of the digital control lines may have more weight in tuning (e.g., when the weights are proportional to powers of two, binary tuning may be performed). Similarly, phase signal S3 may be provided to a control terminal or offset terminal of secondary laser 152 that controls secondary laser 152 to adjust the phase and/or frequency of the emitted optical local oscillator signal LO2. If desired, some or all of downconversion circuitry 166 may be omitted.

DFD 104 may be implemented in any desired clocking circuitry 31 (e.g., clocking circuitry that clocks a radio mixer such as radio mixer 109 of FIG. 8). In implementations where clock signal SIGOUT of FIG. 8 is an optical signal, control signal SIGIN may be an optical signal if desired (e.g., a self-injection locking signal). In these implementations, signal source 100 may be a laser. The laser may, for example, include a laser cavity between two mirrors that keep photons within the laser cavity. If no self-injection is performed, both mirrors are 100% reflective. However, when self-injection is performed, one of the mirrors is less than 100% reflective, allowing an optical control signal SIGIN to be transmitted into the laser cavity from loop path 106 through the mirror. The self-injected photons from the optical control signal may have been cleaned (de-correlated) of phase noise and may therefore help the laser to output clock signal SIGOUT (e.g., an optical local oscillator signal) with reduced phase noise.

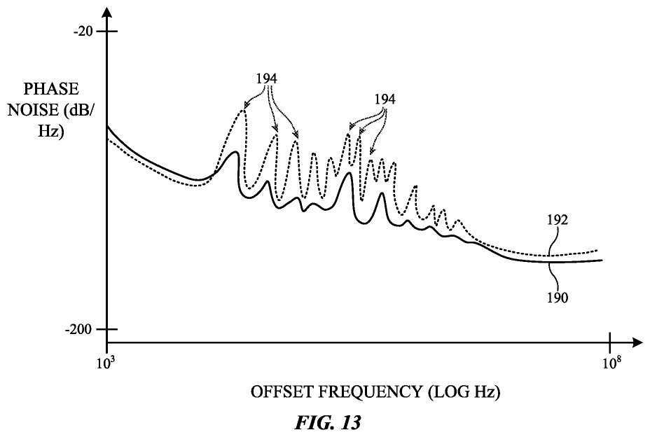

FIG. 13 is a plot showing how multiple delay circuits 144 in delay circuitry 116 (FIGS. 10 and 11) may help to reduce phase noise in clock signal SIGOUT. The horizontal axis of FIG. 13 plots frequency (e.g., in Hz on a logarithmic scale). The vertical axis of FIG. 13 plots phase noise (e.g., in dB/Hz). Curve 192 plots the phase noise of clocking circuitry 31 when delay circuitry 116 includes only a single delay circuit 144. Curve 190 plots the phase noise when delay circuitry 116 includes multiple delay circuits 144 arranged in parallel (FIG. 10) and/or series (FIG. 11). As shown by curves 190 and 192, adding multiple digital delays to delay circuitry 116 may serve to smooth spurious signals 194 in the phase noise of clocking circuitry 31. Curves 190 and 192 may have other shapes in practice.

The optical and/or electro-optical components described herein (e.g., MZM modulator(s), waveguide(s), phase shifter(s), UTC PD(s), etc.) may be implemented with or using plasmonics technology if desired. For example, the optical mixers described herein may be plasmonic-based optical modulators.

Device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The methods and operations described above in connection with FIGS. 1-13 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry 18 of FIG. 1, etc.). The processing circuitry may include microprocessors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. An electronic device comprising:
a signal source configured to generate a clock signal;
a loop path that couples an output of the signal source to an input of the signal source; and
a frequency discriminator disposed on the loop path, the frequency discriminator including
a converter having an input communicably coupled to the output of the signal source,
a digital mixer having an output communicably coupled to the input of the signal source,
a digital delay coupled between the converter and the digital mixer, and
a digital phase shifter coupled between the converter and the digital mixer in parallel with the digital delay.

2. The electronic device of claim 1, wherein the converter is configured to convert the clock signal into a digital signal, the digital delay is configured to generate a delayed signal by applying a time delay to the digital signal, the digital phase shifter is configured to generate a phase shifted signal by applying a phase shift to the digital signal, and the mixer is configured to generate a control signal by mixing the phase shifted signal with the delayed signal.

3. The electronic device of claim 2, wherein the phase shift is a 90-degree phase shift.

4. The electronic device of claim 2, wherein the signal source is configured to adjust the clock signal based on the control signal.

5. The electronic device of claim 2, the frequency discriminator further comprising:
an additional converter coupled between an output of the digital mixer and the input of the signal source, wherein the additional converter is configured to convert the control signal from a digital domain to an analog domain.

6. The electronic device of claim 5, the frequency discriminator further comprising:
a filter coupled between an output of the additional converter and the input of the signal source.

7. The electronic device of claim 1, wherein the converter comprises a time-to-digital converter (TDC).

8. The electronic device of claim 7, the frequency discriminator further comprising:
a digital-to-time converter (DTC) coupled between the output of the digital mixer and the input of the signal source.

9. The electronic device of claim 1, wherein the converter comprises an analog-to-digital converter (ADC).

10. The electronic device of claim 1, the frequency discriminator further comprising:
a digital-to-analog converter (DAC) coupled between the output of the digital mixer and the input of the signal source.

11. The electronic device of claim 1, wherein the digital delay comprises a set of delay stages coupled in parallel between the converter and the digital mixer.

12. The electronic device of claim 1, wherein the digital delay comprises a set of delay stages coupled in series between the converter and the digital mixer.

13. The electronic device of claim 1, wherein the signal source comprises a laser and the clock signal is an optical local oscillator (LO) signal, the electronic device further comprising:
an antenna radiating element; and
a photodiode configured to produce an antenna current on the antenna radiating element based on the optical LO signal.

14. The electronic device of claim 13, further comprising:
downconversion circuitry disposed on the loop path between the frequency discriminator and the output of the signal source, the downconversion circuitry being configured to convert the optical LO signal into a radio-frequency signal.

15. A frequency discriminator comprising:
an input converter;
a digital mixer having a first input coupled to an output of the input converter over a first path and having a second input coupled to the output of the input converter over a second path parallel to the first path;
a digital delay circuit disposed on the first path;
a digital phase shifter disposed on the second path; and
an output converter coupled to an output of the digital mixer.

16. The frequency discriminator of claim 15, wherein the input converter is configured to receive a clock signal and is configured to convert the clock signal into a digital signal, the digital delay circuit is configured to generate a delayed signal based on the digital signal, the digital phase shifter is configured to generate a phase shifted signal by applying a 90-degree phase shift to the digital signal, the mixer is configured to generate a control signal indicative of a phase noise of the clock signal by mixing the delayed signal with the phase shifted signal, and the output converter is configured to convert the control signal from a digital domain to an analog domain.

17. The frequency discriminator of claim 15, wherein the input converter comprises a time-to-digital converter (TDC) or an analog-to-digital converter (ADC).

18. The frequency discriminator of claim 15, wherein the output converter comprises a digital-to-time converter (DTC) or a digital-to-analog converter (DAC).

19. An electronic device comprising:
an antenna radiating element;
a photodiode coupled to the antenna radiating element;
a first light source configured to generate a first optical local oscillator (LO) signal that illuminates the photodiode;
a second light source configured to generate a second optical LO signal that illuminates the photodiode; and
a frequency discriminator coupled between an output of the first light source and an input of the first light source, the frequency discriminator including
a converter configured to convert an input signal into a digital signal, and
digital circuitry configured to generate a control signal based on the digital signal, the control signal being indicative of a phase noise of the input signal.

20. The electronic device of claim 19, further comprising:
a phase detector coupled between an output of the second light source and an input of the second light source; and
downconversion circuitry coupled between the outputs of the first and second light sources, an input of the phase detector, and an input of the frequency discriminator.
